(19) United States
(12) Patent Application Publication
(10) Pub. No.: US 2009/0266393 A1
(43) Pub. Date: Oct. 29, 2009

(54) Thermoelectric generator with concentration cell

(76) Inventor: Ingo Jahns, Berlin (DE)

Correspondence Address: SHUTTLEWORTH & INGERSOLL, P.L.C., 115 3RD STREET SE, SUITE 500, P.O. BOX 2107, CEDAR RAPIDS, IA, 52406, US

(21) Appl. No.: 12/453,132

(22) Filed: Apr. 29, 2009

(30) Foreign Application Priority Data
Apr. 29, 2008 (DE) 10 2008 021 450.7

(51) Int. Cl. H01L 35/34; F02C 6/04; H01L 35/30

(52) U.S. Cl. 136/201; 60/784; 136/205

(57) ABSTRACT

A thermoelectric generator (1) includes a first electrode (5) in a first chamber (11), a second electrode (6) in a second chamber (14), a heating device (19) and an electrolyte cycle, which connects the first chamber (11) to the second chamber (14). The electrolyte cycle, the first chamber (11) and the second chamber (14) receive an electrolytic solution (16) and the heating device (19) heats the electrolytic solution (16) of the first chamber (11).

This application claims priority to German Patent Application DE102008021350.7 filed Apr. 29, 2008, the entirety of which is incorporated by reference herein.

The present invention relates to a generator for the production of electrical power. In particular, this invention relates to a generator for an aircraft turbine.

Jet engines include a compressor, a combustion chamber and a turbine. In order to improve efficiency, it has been proposed to extract heat from the turbine gas and supply it to the compressor via heat exchangers, see for example U.S. Pat. No. 7,007,487 B2.

Currently, the electrical energy required for the operation of the jet engine is produced by a generator. The generator consumes energy while it is driven by the main shaft via a gearbox.

However, the exhaust gas energy could also be utilized for the production of electrical energy. This would improve the thermal efficiency of the cycle. Without the need for a mechanically driven generator, mechanical efficiency would likewise be improved.

A broad aspect of the present invention is to provide a generator, which produces electrical power from thermal energy, while being simply and cost-effectively designed.

It is known from chemistry that electrical energy can be produced from electrode potential differences. Most customary is the Daniell cell in which substances with different electrode potentials are electro-conductively connected. However, different concentrations of electrolytic solutions (concentration cell) and different temperatures will also produce a potential difference. Electrolytic solutions with high concentration and high temperature produce a higher electrode potential than electrolytic solutions with low concentration and low temperature.

These three approaches of providing different potential differences can also be used together for the production of electrical energy. Thus, a combination of galvanic cell and thermal generator is obtained.

Accordingly, the present invention provides a thermoelectric generator which has a first electrode in a first chamber, a second electrode in a second chamber, a heating device and an electrolyte cycle. The electrolyte cycle connects the first chamber to the second chamber, with both the electrolyte cycle and the first and the second chamber being filled with an electrolytic solution. The heating device is used for heating the electrolytic solution of the first chamber.

Furthermore, in accordance with the present invention, a gas turbine, in particular an aircraft jet engine, is provided which includes an above-described thermoelectric generator.

Here, it is particularly advantageous to remove the required heat from the exhaust gas section of the gas turbine, for example. For further increase of the efficiency of the thermoelectric generator, the electrolytic solution can be cooled in a bypass airflow of the gas turbine.

The present invention further provides a method for the production of electrical power by use of a first electrode in a first chamber, a second electrode in a second chamber and an electrolyte cycle which connects the first chamber to the second chamber. In accordance with the present invention, the following steps will be considered:

The system including the two chambers and the electrolyte cycle is filled with electrolytic solution. The electrolytic solution of the first chamber is heated before it is supplied to the chamber and/or when it is in the chamber. Furthermore, at least partly cooled electrolytic solution is transferred from the first chamber to the second chamber. Advantageously, the electrolytic solution is actively cooled in the process.

The present invention is more fully described in light of the accompanying drawing showing a preferred embodiment. In the drawing,

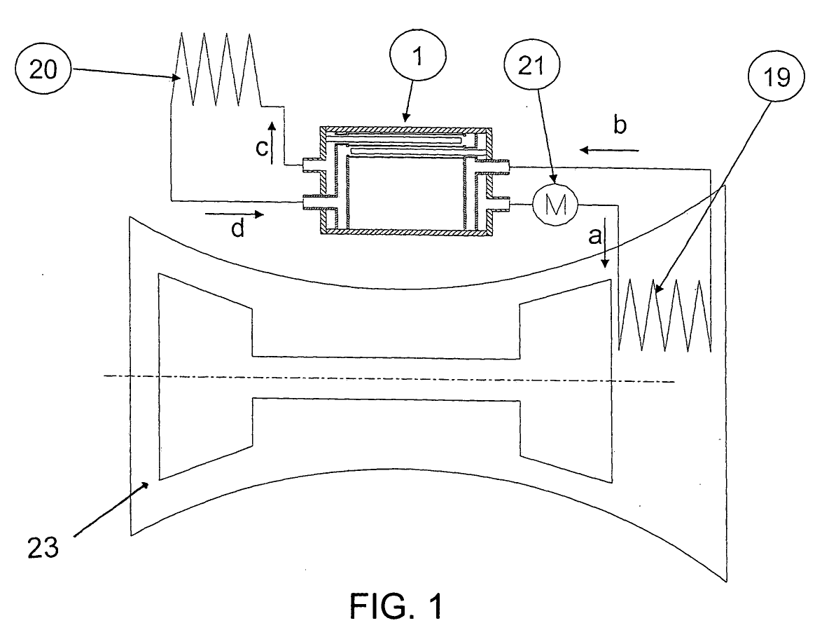

FIG. 1 shows a gas turbine in accordance with the present invention with an inventive thermoelectric generator, and

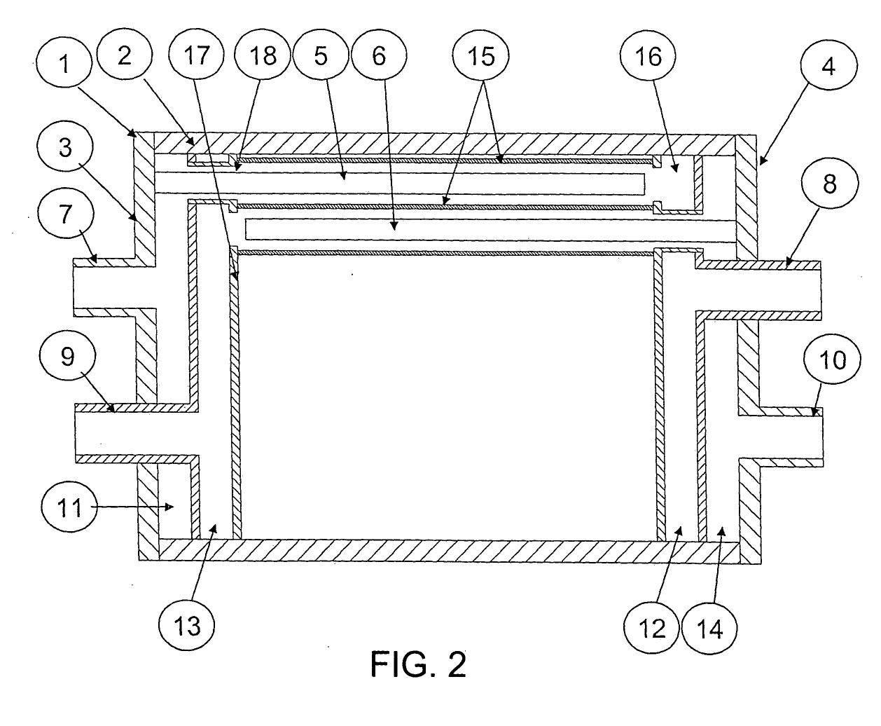

FIG. 2 is a detail view of the thermoelectric generator in accordance with the present invention.

FIG. 1 shows an aircraft turbine 23, a thermoelectric generator 1, cooling fins or a heat exchanger 20, heating coil or heat exchanger 19 and a motor or pump 21. The heating coil 19 is arranged in the exhaust gas section of the aircraft engine 23. The cooling fins 20 are arranged in the bypass airflow of the aircraft turbine 23. The pump 21 delivers the electrolytic solution in an electrolyte cycle of the thermoelectric generator 1.

The operation of the generator is now described in conjunction with the detail view of the thermoelectric generator 1 in FIG. 2.

Electrical power is produced in a heat/power generator 1. Arranged on the outside is the casing 2. Multiple electrodes 5, 6 are integrated inside the two front covers 3, 4. Electrical power can be tapped on the outside of the covers 3, 4.

The two covers 3, 4 are electrically insulated to avoid short circuiting, for example by using a nonconductor for the material of the casing 2. The front faces (covers 3, 4) are each provided with two openings 7, 8, 9, 10 for the passage of an electrolytic solution 16. Behind each of the front covers, two chambers 11, 12, 13, 14 are provided, which are separated from each other, with each of the chambers featuring an inflow opening 7, 8, 9, 10 from the front face of the covers 3, 4.

To avoid mixing of the electrolytic solution, the chambers are sealed against each other, with the wall 17, for example, being made of a non-conductive material. The same applies for the passages 18 of the electrodes 5, 6.

Arranged in the center of the thermoelectric generator 1 is a diaphragm 15. The latter is formed such that, for example by a honeycomb configuration, a high packing density of the electrodes can be obtained. The electrodes 5, 6 alternately protrude into these honeycombs of the diaphragm 15 and are flown by the electrolytic solution 16.

Copper can for example be used as electrode material. It can be provided as a pure metal body, but also applied as a coating on a porous substrate to increase the surface area. In the event of a copper electrode being used, the electrolytic solution could be copper sulfate, for example. The present invention also provides for other electrodes/electrolytic solutions. Also possible would be the use of lead oxide, for example in the form of a lead storage battery.

The configuration of the electrical power generator according to the present invention provides for both co-current and counter-current flow of the electrolytic solution.

For the production of electrical power, hot, ion-enriched electrolytic solution is fed over the rod-type electrodes of a first side, while another side is supplied with cold, ion-depleted electrolytic solution.

In the initial state, the electrolytic solution in the thermoelectric generator 1 is in equilibrium, i.e. equal temperature, equal concentration. The electrolytic solution is heated by a heating coil 19 in the turbine and fed to the electrode rods 5. The electrode potential of this cell is thereby increased. In the process, the electrode absorbs copper ions. As a result, the concentration of copper ions in the electrolytic solution decreases. The depleted/hot electrolytic solution issues on the other side of the thermoelectric generator 1 and is cooled via the cooling fins 20 (for example in the bypass airflow). This depleted, cold electrolytic solution is now supplied to the other electrode rods 6. It therefore has a low electrode potential. Copper is dissolved while releasing electrons. The electrons travel via the electric circuit to the opposite electrode 5 providing there for the deposition of copper on the electrode. The cold, ion-enriched electrolytic solution issues on the other side of the thermoelectric generator 1. It is again heated by the heating coil 19. The cycle starts again. For electric compensation, sulfate ions are exchanged via the diaphragm 15.

The cycle can be driven passively, i.e. without motor. However, the boiling temperature point can be raised by building up a pressure via a pump 21 prior to heating the electrolytic solution. As a result, the electrolytic solution can take up more heat.

Complete dissolution of the electrodes would interrupt the cycle. To avoid this, the supply lines are provided with relays/valves 22 which alternately feed hot and cold electrolytic solution over the electrodes to alternately build up and break down the electrodes 5, 6. Thus, the arrangement according to the present invention also enables alternating current to be produced, although with low frequency only.

Accordingly, the operation of the thermoelectric generator is described hereunder in conjunction with the four arrows A, B, C, D of FIG. 1:

Cold electrolytic solution with high concentration of copper ions (A) flows into the heating coil 19 and, upon being heated there, flows as hot electrolytic solution with high concentration of copper ions (B) into the thermoelectric generator. From this thermoelectric generator 1, the hot electrolytic solution with low concentration of copper ions (C) flows into the cooling fins 20 and is cooled there. Subsequently, the cold electrolytic solution with low concentration of copper ions (D) flows into the thermoelectric generator 1.

Accordingly, the present invention, by combination of galvanic cell and thermal element, provides an efficient generator for the production of electrical power. This generator is advantageously useable in particular in combination with the utilization of the exhaust gas heat of an engine.

### LIST OF REFERENCE NUMERALS

1 Heat/electrical power generator

2 Casing

3, 4 Front cover

5, 6 Electrode

7 to 10 Opening/inflow opening

11 to 14 Chamber

15 Diaphragm

16 Electrolytic solution

17 Wall

18 Passage

19 Heating coil/heat exchanger

20 Cooling fin/heat exchanger

21 Pump

22 Valve/relay

23 Gas turbine

What is claimed is:

1. A thermoelectric generator comprises:
a first chamber;
a second chamber, the first chamber and the second chamber constructed and arranged to receive an electrolytic solution;
a first electrode positioned in the first chamber;
a second electrode positioned in the second chamber;
a heating device constructed and arranged to heat the electrolytic solution passing through the first chamber, the first chamber and the second chamber being interconnected so that electrolytic solution exiting the first chamber is routed to the second chamber, with a temperature differential between the electrolytic solution in the first chamber and second chamber, respectively, causing an electrolytic action which creates an electrical flow between the first electrode and the second electrode.

2. The thermoelectric generator of claim 1, and further comprising a cooling device for cooling the electrolytic solution before it enters the second chamber.

3. The thermoelectric generator of claim 2, and further comprising a diaphragm separating the first chamber from the second chamber that allows sulfate ions to pass between the chambers.

4. The thermoelectric generator of claim 3, and further comprising a pump to pump the electrolytic solution.

5. The thermoelectric generator of claim 4, and further comprising at least one valve for controlling a direction of flow of the electrolytic solution between the first chamber and the second chamber and thereby altering exposure of the respective electrodes to heated and cooled electrolyte.

6. The thermoelectric generator of claim 5, wherein at least one of the first chamber and the second chamber form a casing of the thermoelectric generator.

7. The thermoelectric generator of claim 1, and further comprising a diaphragm separating the first chamber from the second chamber that allows sulfate ions to pass between the chambers.

8. The thermoelectric generator of claim 1, and further comprising a pump to pump the electrolytic solution.

9. The thermoelectric generator of claim 1, and further comprising at least one valve for controlling a direction of flow of the electrolytic solution between the first chamber and the second chamber and thereby altering exposure of the respective electrodes to heated and cooled electrolyte.

10. A gas turbine, especially an aircraft turbine, comprising:
a gas turbine;
a thermoelectric generator comprising:
a first chamber;
a second chamber, the first chamber and the second chamber constructed and arranged to receive an electrolytic solution;
a first electrode positioned in the first chamber;
a second electrode positioned in the second chamber;
a heating device constructed and arranged to heat the electrolytic solution passing through the first chamber, the first chamber and the second chamber being interconnected so that electrolytic solution exiting the first chamber is routed to the second chamber, with a temperature differential between the electrolytic solution in the first chamber and second chamber, respectively, causing an electrolytic action which creates an electrical flow between the first electrode and the second electrode.

11. The gas turbine of claim 10, and further comprising a cooling device for cooling the electrolytic solution before it enters the second chamber using a bypass airflow of the gas turbine.

12. The gas turbine of claim 11, and further comprising a diaphragm separating the first chamber from the second chamber that allows sulfate ions to pass between the chambers.

13. The gas turbine of claim 12, and further comprising a pump to pump the electrolytic solution.

14. The gas turbine of claim 13, and further comprising at least one valve for controlling a direction of flow of the electrolytic solution between the first chamber and the second chamber and thereby altering exposure of the respective electrodes to heated and cooled electrolyte.

15. The gas turbine of claim 14, wherein at least one of the first chamber and the second chamber form a casing of the thermoelectric generator.

16. The gas turbine of claim 10, and further comprising a diaphragm separating the first chamber from the second chamber that allows sulfate ions to pass between the chambers.

17. The gas turbine of claim 10, and further comprising a pump to pump the electrolytic solution.

18. The gas turbine of claim 10, and further comprising at least one valve for controlling a direction of flow of the electrolytic solution between the first chamber and the second chamber and thereby altering exposure of the respective electrodes to heated and cooled electrolyte.

19. A method for the production of electrical power, comprising:
providing a first electrode in a first chamber and a second electrode in a second chamber;
creating an electrolyte cycle, which connects the first chamber to the second chamber, including:
filling the first chamber and the second chamber with an electrolytic solution,
creating a flow of electrolytic solution between the first chamber and the second chamber,
heating the electrolytic solution flowing into the first chamber, and
cooling the electrolytic solution flowing into the second chamber, with a temperature differential between the electrolytic solution in the first chamber and second chamber, respectively, causing an electrolytic action which creates an electrical flow between the first electrode and the second electrode.

20. The method of claim 19, and further comprising providing a diaphragm separating the first chamber from the second chamber that allows sulfate ions to pass between the chambers.
